(19) United States
(12) Patent Application Publication
(10) Pub. No.: US 2003/0082888 A1
(43) Pub. Date: May 1, 2003

(54) Method of incorporating deep trench into shallow trench isolation process without added masks

(76) Inventor: Ching-Fu Lin, Taipei City (TW)

Correspondence Address: POWELL, GOLDSTEIN, FRAZER & MURPHY LLP, P.O. BOX 97223, WASHINGTON, DC, 20090-7223, US

(21) Appl. No.: 10/150,074

(22) Filed: May 20, 2002

Related U.S. Application Data
(60) Provisional application No. 60/336,201, filed on Oct. 31, 2001.

(51) Int. Cl. H01L 21/76

(52) U.S. Cl. 438/424

(57) ABSTRACT

The present invention provides a method of forming a deep trench device and a shallow trench isolation comprising providing a semiconductor substrate having a first opening thereon. A dielectric layer is deposited on the semiconductor substrate and into the first opening. A mask layer is formed on the first dielectric layer. The mask layer is transferred a pattern consisting of database of reverse shallow trench isolation and database of the deep trench. The partial first dielectric layer and semiconductor substrate are removed to form a second opening below the first opening. The deep trench device is formed in the second opening and the shallow trench isolation in the first opening.

### BACKGROUND OF THE INVENTION

1. Field of the Invention

The present invention relates to a method of forming semiconductor device, and more particularly relates to a method of process incorporating deep trench database into reverse database of shallow trench isolation.

2. Description of the Prior Art

As the integration densities increase, it is desirable in the semiconductor industry to decrease the storage capacitor size while maintaining the charge storage capacity for DRAM devices. One approach to this problem in the prior art is to utilize a deep trench capacitor. Such capacitor structures have reduced surface space while maintaining the charge storage capacity of the capacitor. On the other hand, the deep trench is also utilized as a shielding structure for mixed signal devices.

Depicted in FIG. 1A, a deep trench consisting of a conductive layer 125, such as polysilicon layer, and a liner oxide layer 123 is in a silicon substrate 110 having a nitride layer 114 thereon. A photoresist layer 116 on the nitride layer 114 is transferred the pattern of shallow trench isolation.

Next, the opening 127 for the formation of the shallow trench isolation is formed on the deep trench, shown in FIG. 1B. The silicon substrate 110 is etched to form the shallow trench isolation. Unfortunately, when the silicon substrate 110 around the deep trench is removed, the liner oxide layer 123 isn't removed, such that the micro-trench would occur in the opening 127 of the shallow trench isolation. Furthermore, it is difficult to simultaneously remove the silicon substrate and the liner oxide layer because of consideration of the design of mixed semiconductor devices. Thus, the micro-trench degrades the characteristics of the shallow trench isolation and the deep trench devices.

The other problem is about to the number of the photolithography mask and alignment mark problem. Other practitioners have proposed solutions to the non-readable alignment mark problem. U.S. Pat. No. 5,627,100 (Lee) shows a method for eliminating the window mask process when using a CMP process. U.S. Pat. No. 5,128,283 (Tanaka) shows a method of forming mask alignment marks. U.S. Pat. No. 5,356,513 (Burke) shows a method of forming a polished stop planarization using chemical-mechanical polishing (CMP). U.S. Pat. No. 6,043,133 (Jang et al) shows a method of removing an shallow trench isolation (STI) oxide layer from over alignment marks.

### SUMMARY OF THE INVENTION

It is an object of the invention to provide a method of forming a shallow trench isolation and a deep trench device. The pattern of the deep trench database is added into the database of a reverse tone shallow trench isolation, which can reduce the mask number.

It is another object of the invention to provide a method of process incorporating a deep trench database into reverse database of shallow trench isolation. Residue of a conductive layer from etching back for deep trench device improves the detection of end point in chemical mechanical polishing.

The present invention provides a method of forming a deep trench device and a shallow trench isolation comprising providing a semiconductor substrate having a first opening thereon. A dielectric layer is deposited on the semiconductor substrate and into the first opening. A mask layer is formed on the first dielectric layer. The mask layer is transferred a pattern consisting of database of reverse shallow trench isolation and database of the deep trench. The partial first dielectric layer and semiconductor substrate are removed to form a second opening below the first opening. The deep trench device is formed in the second opening and the shallow trench isolation in the first opening.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIGS. 1A-1B are the series cross-sectional schematic diagrams illustrating the formation of deep trench and shallow trench isolation thereon in accordance with the prior art; and

FIGS. 2A-2F are the series cross-sectional schematic diagrams illustrating the formation of shallow trench isolation and deep trench device in accordance with the present invention.

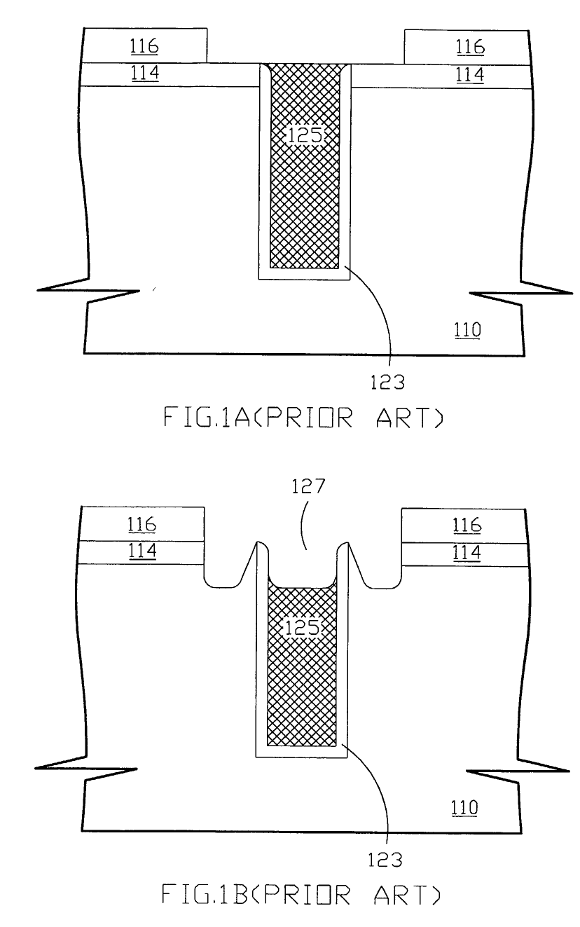

### DESCRIPTION OF THE PREFERRED EMBODIMENT

The semiconductor devices of the present invention are applicable to a broad range of semiconductor devices and can be fabricated from a variety of semiconductor materials. The following description discusses several presently preferred embodiments of the semiconductor devices of the present invention as implemented in silicon substrates, since the majority of currently available semiconductor devices are fabricated in silicon substrates and the most commonly encountered applications of the present invention will involve silicon substrates. Accordingly, application of the present invention is not intended to be limited to those devices fabricated in silicon semiconductor materials, but will include those devices fabricated in one or more of the available semiconductor materials.

The present invention provides a method of forming a deep trench device and a plurality of shallow trench isolation devices. The method comprises providing a semiconductor substrate having a plurality of first openings thereon. A dielectric layer is deposited on the semiconductor substrate and into the first openings. A mask layer is formed on the dielectric layer, which is transferred a pattern consisting of database of reverse shallow trench isolation and database of the deep trench. The partial dielectric layer that is beside the first openings and partial in one of the first openings is remove, and the partial semiconductor substrate in the one of the first openings is removed to form a second opening below the one of said first openings. The deep trench device is formed in the second opening and the shallow trench isolation devices in the first openings.

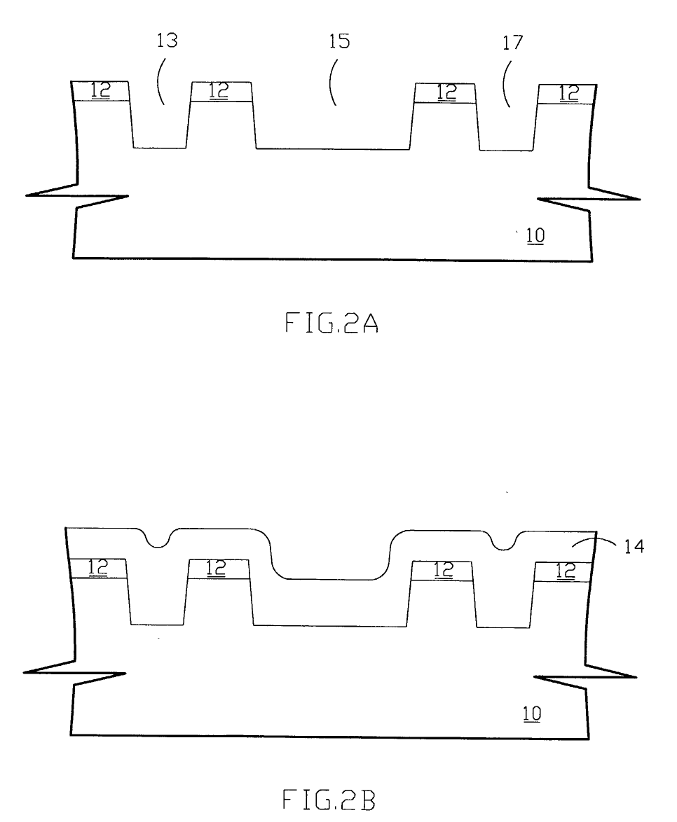

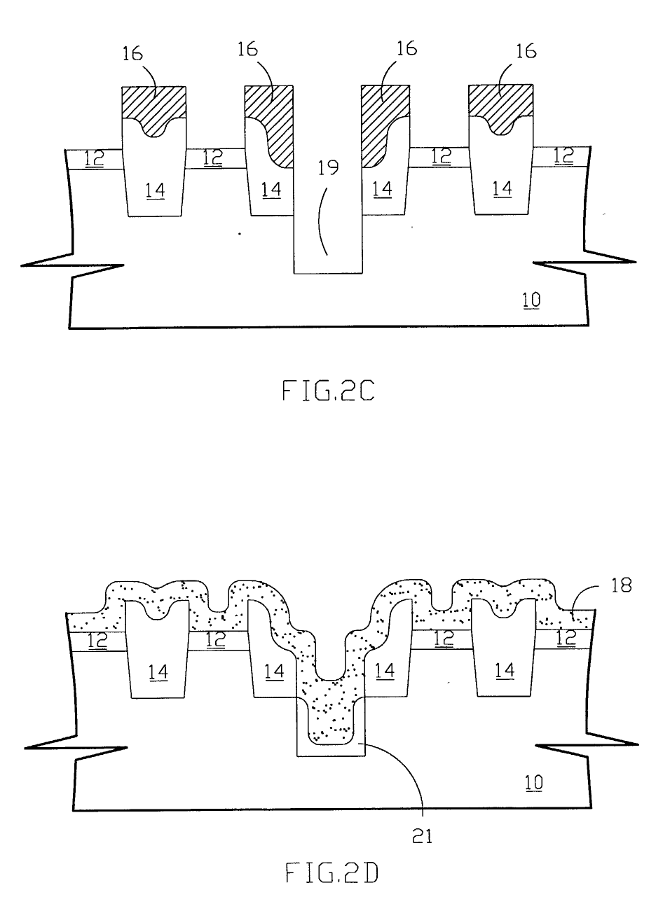

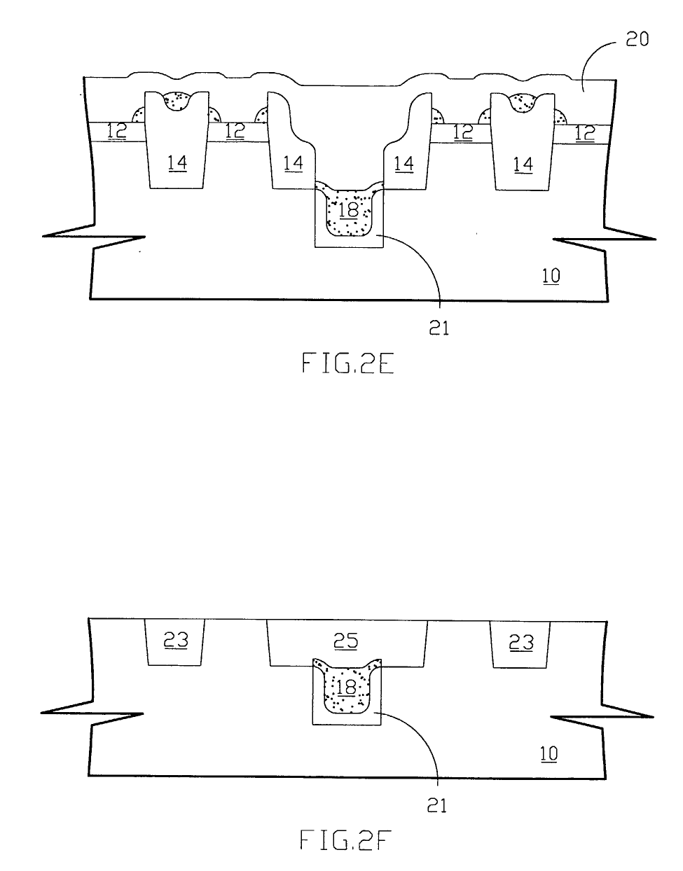

In FIG. 2A, a substrate 10 or semiconductor wafer is provided. A pad oxide layer or thermal oxide layer (not shown) would be formed over the substrate 10. A silicon nitride layer 12 is deposited on top of the substrate 10, whereby multitudes of shallow trench 13, 15 and 17 are formed on the substrate 10. To be specific, the thickness of the silicon nitride layer 12 could be as thin as well to function as hard mask for etch processes of shallow trench isolation and deep trench device.

Then a dielectric layer 14, such as an oxide layer, is deposited on the silicon nitride layer 12 and into the shallow trenches 13, 15, and 17. Next as a key feature of the present invention, a “reverse tone” STI photoresist mask 16 is formed on the dielectric layer 14 and pattern-transferred. To be specific, the “reverse tone” STI photoresist mask 16 has the pattern of reverse STI database in combination of deep trench database. Thus, the conventional mask only for deep trench device is not necessary in the process of the present invention. Next, the partial silicon nitride layer 12, the dielectric layer 14 and the substrate 10 are etched to expose the silicon nitride layer 12 of active regions and form a deep trench 19, depicted in FIG. 2C.

Next, a liner oxide layer 21 is first formed at the sidewall of the deep trench 19, and then a conductive layer 18, such as a polysilicon layer, is deposited over the substrate 10 and into the deep trench 19, as shown in FIG. 2D. The conductive layer 18 is subsequently etched back to form the deep trench device. There maybe polysilicon residue at the corners of the deep trench device or the shallow trench isolation, which is advantageous for following process of the chemical mechanical polishing to detect an end point. Then the other dielectric layer 20, such as an oxide layer, is deposited over the substrate 10 and the shallow trench isolation, depicted in FIG. 2E.

Next, the dielectric layer 20 is planarized by the chemical mechanical polishing, shown in FIG. 2F. Thus, multitudes of shallow trench isolations 23 and 25 are implemented wherein the shallow trench isolation 25 is above the deep trench device consisting the conductive layer 16 and the liner oxide layer 21.

Of course, it is to be understood that the invention need not be limited to these disclosed embodiments. Various modification and similar changes are still possible within the spirit of this invention. In this way, the scope of this invention should be defined by the appended claims.

What is claimed is:

1. A method of forming a deep trench device and a shallow trench isolation, said method comprising:
providing a semiconductor substrate having a first opening thereon;
depositing a first dielectric layer on said semiconductor substrate and into said first opening;
forming a mask layer on said first dielectric layer, said mask layer transferred a pattern consisting of database of reverse shallow trench isolation and database of said deep trench device;
removing partial said first dielectric layer and partial said semiconductor substrate to form a second opening below said first opening;
forming said deep trench device in said second opening; and
forming said shallow trench isolation in said first opening.

2. The method according to claim 1, wherein said providing step comprises a silicon nitride layer on partial said semiconductor substrate without said first opening.

3. The method according to claim 2, wherein said step of removing partial said first dielectric layer and partial said semiconductor substrate further comprises removing partial said silicon nitride layer.

4. The method according to claim 1, wherein said forming said deep trench device comprises:
forming a liner oxide layer at a sidewall of said second opening;
depositing a conductive layer in said second opening and on said semiconductor substrate; and
etching back said conductive layer to form said deep trench device.

5. The method according to claim 4, wherein said conductive layer comprises a polysilicon layer.

6. The method according to claim 1, wherein said forming said shallow trench isolation comprises:
depositing a second dielectric layer over said semiconductor substrate; and
planarizing said second dielectric layer by chemical mechanical polishing.

7. The method according to claim 1, wherein said step of removing partial said first dielectric layer and partial said semiconductor substrate is to remove said first dielectric layer that is beside said first opening and on said second opening.

8. The method according to claim 1, wherein said first opening has a size larger than said second opening.

9. A method of forming a deep trench device and a plurality of shallow trench isolation devices, said method comprising:
providing a semiconductor substrate having a plurality of first openings thereon;
depositing a dielectric layer on said semiconductor substrate and into said first openings;
forming a mask layer on said dielectric layer, said mask layer transferred a pattern consisting of database of reverse shallow trench isolation and database of said deep trench device;
removing partial said dielectric layer that is beside said first openings and partial in one of said first openings, and removing partial said semiconductor substrate in said one of said first openings to form a second opening below said one of said first openings;
forming said deep trench device in said second opening; and
forming said shallow trench isolation devices in said first openings.

10. The method according to claim 9, wherein said providing step comprises a silicon nitride layer on partial said semiconductor substrate without said first openings.

11. The method according to claim 9, wherein said dielectric layer comprises an oxide layer.

12. The method according to claim 9, wherein said forming said deep trench device comprises:
forming a liner oxide layer at a sidewall of said second opening;
depositing a polysilicon layer in said second opening and on said semiconductor substrate; and
etching back said polysilicon layer to form said deep trench device.

13. The method according to claim 9, wherein said forming said shallow trench isolation devices comprises:
depositing an oxide layer over said semiconductor substrate; and
planarizing said oxide layer by chemical mechanical polishing.
